(19) United States
(12) Patent Application Publication
(10) Pub. No.: US 2015/0267292 A1
(43) Pub. Date: Sep. 24, 2015

(54) CLEANING METHOD OF SILICON OXIDE FILM FORMING APPARATUS, SILICON OXIDE FILM FORMING METHOD, AND SILICON OXIDE FILM FORMING APPARATUS

(71) Applicant: TOKYO ELECTRON LIMITED, Tokyo (JP)

(72) Inventors: Cheoljung KIM, Oshu-Shi (JP); Toshiyuki IKEUCHI, Nirasaki City (JP); Akira SHIMIZU, Nirasaki City (JP)

(21) Appl. No.: 14/662,663

(22) Filed: Mar. 19, 2015

(30) Foreign Application Priority Data
Mar. 20, 2014 (JP) 2014-058129

(51) Int. Cl. C23C 16/44; C23C 16/455; C23C 16/40; C23C 16/52

(52) U.S. Cl. CPC C23C 16/4405; C23C 16/52; C23C 16/455; C23C 16/401

(57) ABSTRACT

A cleaning method of a silicon oxide film forming apparatus for removing a deposit adhering to the inside of the silicon oxide film forming apparatus after a silicon oxide film is formed on a workpiece by supplying a process gas into a reaction chamber of the silicon oxide film forming apparatus. The cleaning method includes oxidizing the deposit adhering to the inside of the silicon oxide film forming apparatus by supplying an oxidizing gas into the reaction chamber, and cleaning the inside of the silicon oxide film forming apparatus by supplying a cleaning gas into the reaction chamber and removing the oxidized deposit.

### CROSS-REFERENCE TO RELATED APPLICATION

This application claims the benefit of Japanese Patent Application No. 2014-058129, filed on Mar. 20, 2014, in the Japan Patent Office, the disclosure of which is incorporated herein in its entirety by reference.

### TECHNICAL FIELD

The present disclosure relates to a cleaning method of a silicon oxide film forming apparatus, a silicon oxide film forming method, and a silicon oxide film forming apparatus.

### BACKGROUND

As a silicon oxide film forming method, there is proposed an ALD (Atomic Layer Deposition) method for forming a high-quality silicon oxide film on a workpiece, e.g., a semiconductor wafer, at a low temperature. For example, a method for forming a thin film at a low temperature is known.

A silicon oxide film as formed is deposited on (adheres to) not only the surface of a semiconductor wafer but also the internal parts of a processing apparatus such as the inner wall of a reaction tube or different kinds of jigs. Thus, a deposit adhering to the inner wall of the reaction tube and so forth is removed by supplying cleaning gas such as hydrogen fluoride (HF) or the like into the reaction tube.

However, even if the cleaning gas is supplied at a low temperature, e.g., at room temperature (RT), a film tends to remain in the lower portion of the reaction tube. Such residual film becomes a cause of the generation of particles. This poses a problem reducing productivity.

### SUMMARY

Some embodiments of the present disclosure provide a cleaning method of a silicon oxide film forming apparatus, a silicon oxide film forming method, and a silicon oxide film forming apparatus, which are capable of suppressing generation of particles even at a low temperature such as a room temperature or the like and capable of improving productivity.

According to one embodiment of the present disclosure, there is provided a cleaning method of a silicon oxide film forming apparatus for removing a deposit adhering to the inside of the silicon oxide film forming apparatus after a silicon oxide film is formed on a workpiece by supplying a process gas into a reaction chamber of the silicon oxide film forming apparatus. The cleaning method includes oxidizing the deposit adhering to the inside of the silicon oxide film forming apparatus by supplying an oxidizing gas into the reaction chamber, and cleaning the inside of the silicon oxide film forming apparatus by supplying a cleaning gas into the reaction chamber and removing the oxidized deposit.

According to another embodiment of the present disclosure, there is provided a silicon oxide film forming method, which includes: forming a silicon oxide film on a workpiece; and cleaning the inside of a silicon oxide film forming apparatus according to the aforementioned cleaning method.

According to another embodiment of the present disclosure, there is provided a silicon oxide film forming apparatus for forming a silicon oxide film on a workpiece by supplying a process gas into a reaction chamber which accommodates the workpiece therein. The silicon oxide film forming apparatus includes: an oxidizing gas supply unit configured to supply an oxidizing gas into the reaction chamber; a cleaning gas supply unit configured to supply a cleaning gas into the reaction chamber; and a control unit configured to control respective units of the apparatus. The control unit is configured to control the oxidizing gas supply unit so as to supply the oxidizing gas into the reaction chamber and remove carbon from a deposit adhering to the inside of the apparatus by oxidizing the deposit. Further, the control unit is configured to control the cleaning gas supply unit so as to supply the cleaning gas into the reaction chamber and clean the inside of the silicon oxide film forming apparatus by removing the deposit from which carbon is removed.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a view showing a processing apparatus according to one embodiment of the present disclosure.

FIG. 2 is a view showing a configuration of a control unit employed in the processing apparatus shown in FIG. 1.

FIG. 3 is a view explaining a silicon oxide film forming method.

FIG. 4 is a view explaining a cleaning method of a processing apparatus.

FIGS. 5A and 5B are views showing XPS analysis results.

FIG. 6 is a view showing a processing apparatus according to another embodiment of the present disclosure.

### DETAILED DESCRIPTION

Hereinafter, a cleaning method of a silicon oxide film forming apparatus, a silicon oxide film forming method, and a silicon oxide film forming apparatus according to some embodiments of the present disclosure will now be described in detail with reference to the accompanying drawings. In the drawings, like reference numerals denote like elements. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

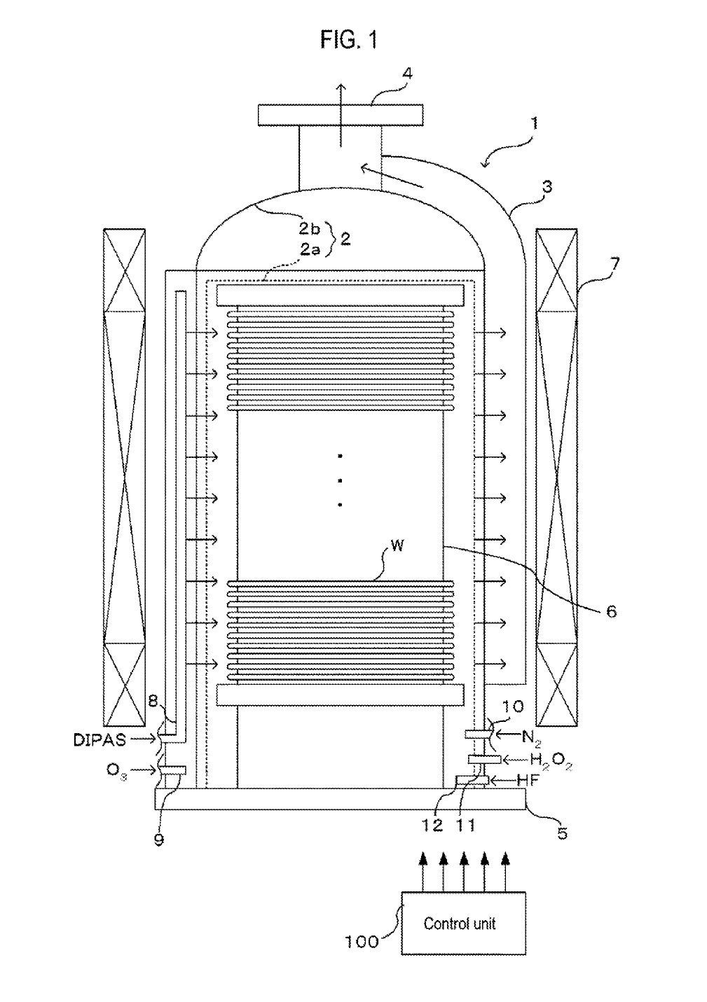

In the present embodiments, the description will be made by taking as an example a case in which a batch-type vertical processing apparatus is used as the silicon oxide film forming apparatus of the present disclosure. FIG. 1 shows the configuration of the processing apparatus according to one embodiment.

As shown in FIG. 1, the processing apparatus 1 includes a reaction tube 2 whose longitudinal direction extends in the vertical direction. The reaction tube 2 has a double tube structure which includes an inner tube 2a and a roofed outer tube 2b configured to cover the inner tube 2a and is spaced apart from the inner tube 2a. The sidewalls of the inner tube 2a and the outer tube 2b have a plurality of openings as indicated by arrows in FIG. 1. The inner tube 2a and the outer tube 2b are made of a material superior in heat resistance and corrosion resistance, e.g., quartz.

An exhaust part 3 for discharging gas within the reaction tube 2 is disposed at one side of the reaction tube 2. The exhaust part 3 is formed to extend upward along the reaction tube 2 and is configured to communicate with the reaction tube 2 through the openings formed in the sidewall of the reaction tube 2. The upper end portion of the exhaust part 3 is connected to an exhaust port 4 arranged in the upper portion of the reaction tube 2. An exhaust pipe (not shown) is connected to the exhaust port 4. Pressure regulating mechanisms such as a valve (not shown) and a vacuum pump 127 to be described later are installed in the exhaust pipe. By the pressure regulating mechanisms, gas supplied from one side of the sidewall of the outer tube 2b (a source gas supply pipe 8) is discharged to the exhaust pipe through the inner tube 2a, the sidewall of the outer tube 2b on the other side, the exhaust part 3 and the exhaust port 4. Thus, the interior of the reaction tube 2 is controlled to a desired pressure (vacuum degree).

A lid 5 is disposed below the reaction tube 2. The lid 5 is made of a material superior in heat resistance and corrosion resistance, e.g., quartz. Further, the lid 5 can be moved up and down by a boat elevator 128 to be described later. If the lid 5 is moved up by the boat elevator 128, the lower end (furnace port) of the reaction tube 2 is closed. If the lid 5 is moved down by the boat elevator 128, the lower end (furnace port) of the reaction tube 2 is opened.

A wafer boat 6 is mounted on the lid 5. The wafer boat 6 is made of, e.g., quartz. The wafer boat 6 is configured such that a plurality of semiconductor wafers W can be accommodated therein in a vertically spaced-apart relationship. Furthermore, a heat insulating container, which prevents an internal temperature reduction of the reaction tube 2 from the furnace port of the reaction tube 2, or a rotary table, on which the wafer boat 6 for accommodating the semiconductor wafers W is rotatably mounted, may be installed on the lid 5, and the wafer boat 6 may be mounted on the heat insulating container or the rotary table. In this case, it becomes easy to uniformly control the temperature of the semiconductor wafers W accommodated within the wafer boat 6.

In the vicinity of the reaction tube 2, heaters 7 formed of, e.g., resistance heating elements, are installed so as to enclose the reaction tube 2. The interior of the reaction tube 2 is heated to a predetermined temperature by the heaters 7. As a result, the semiconductor wafers W accommodated within the reaction tube 2 are heated to the predetermined temperature.

The source gas supply pipe 8 for supplying a source gas into the reaction tube 2 (outer tube 2b) is inserted through the side surface near the lower end portion of the reaction tube 2. The source gas is a Si source which supplies a source material (Si) to be adsorbed to a workpiece. The source gas is used at an adsorption step to be described later. In this embodiment, diisopropylaminosilane (DIPAS) is used as the Si source.

A plurality of supply holes are formed in the source gas supply pipe 8 by a predetermined interval along the vertical direction. The source gas is supplied into the reaction tube 2 (outer tube 2b) via the supply holes. Thus, as indicated by the arrows in FIG. 1, the source gas is supplied into the reaction tube 2 from a plurality of points arranged in the vertical direction.

A first oxidizing gas supply pipe 9 for supplying an oxidizing gas into the reaction tube 2 (outer tube 2b) is inserted through the side surface near the lower end portion of the reaction tube 2. The oxidizing gas is a gas which oxidizes the adsorbed source (Si). The oxidizing gas is used at an oxidation step to be described later. In this embodiment, ozone (O₃) is used as the oxidizing gas.

A nitrogen gas supply pipe 10 for supplying nitrogen (N₂) as a diluting gas and a purge gas into the reaction tube 2 (inner tube 2a) is inserted through the side surface near the lower end portion of the reaction tube 2.

Furthermore, a second oxidizing gas supply pipe 11 for supplying an oxidizing gas into the reaction tube 2 (outer tube 2b) is inserted through the side surface near the lower end portion of the reaction tube 2. The oxidizing gas is a gas for oxidizing a deposit which adheres to the inside of the reaction tube 2 during formation of a silicon oxide film, thereby removing carbon (C) from the deposit. The oxidizing gas is used at an oxidizing step to be described later. In this embodiment, an H₂O₂ gas is used as the oxidizing gas.

A cleaning gas supply pipe 12 for supplying a cleaning gas into the reaction tube 2 (outer tube 2b) is inserted through the side surface near the lower end portion of the reaction tube 2. The cleaning gas is a gas for removing a deposit which adheres to the inside of the reaction tube 2. The cleaning gas is used at a cleaning step to be described later. In this embodiment, a hydrogen fluoride (HF) gas is used as the cleaning gas.

The source gas supply pipe 8, the first oxidizing gas supply pipe 9, the nitrogen gas supply pipe 10, the second oxidizing gas supply pipe 11 and the cleaning gas supply pipe 12 are connected to source gas supply sources (not shown) through mass flow controllers (MFCs) 125 to be described later.

A plurality of temperature sensors 122, e.g., thermocouples, for measuring the internal temperature of the reaction tube 2 and a plurality of pressure gauges 123 for measuring the internal pressure of the reaction tube 2 are disposed within the reaction tube 2.

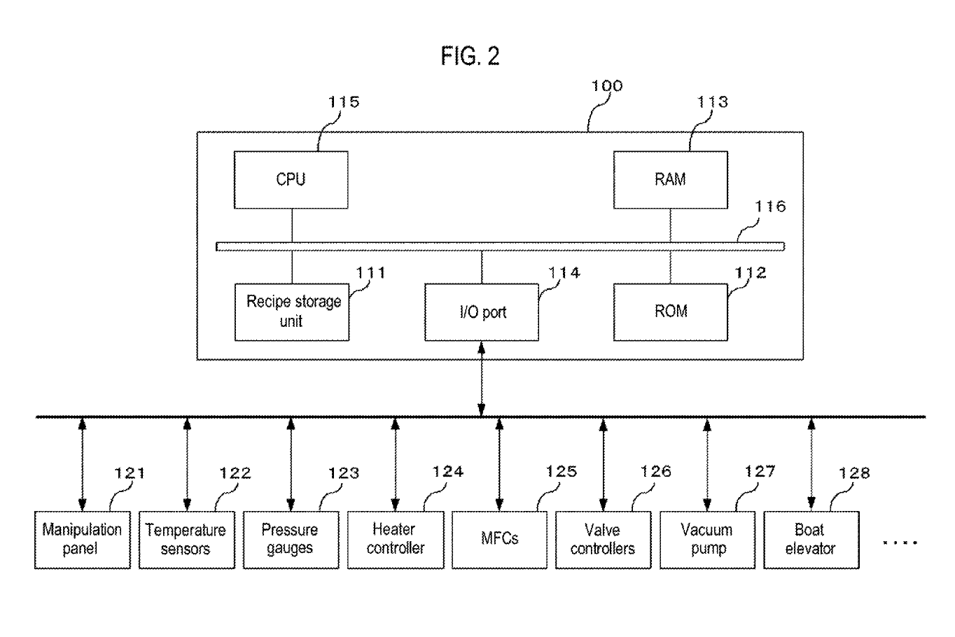

The processing apparatus 1 further includes a control unit 100 configured to control the respective parts of the apparatus. FIG. 2 shows the configuration of the control unit 100. As shown in FIG. 2, a manipulation panel 121, the temperature sensors 122, the pressure gauges 123, a heater controller 124, the MFCs 125, valve controllers 126, the vacuum pump 127, the boat elevator 128 and the like are connected to the control unit 100.

The manipulation panel 121 is provided with a display and manipulation buttons. The manipulation panel 121 transmits operator's instructions to the control unit 100 and displays a variety of information received from the control unit 100 on the display thereof.

The temperature sensors 122 measure the temperatures of the respective parts existing within the reaction tube 2 and within the exhaust pipe, and notify the measured values to the control unit 100. The pressure gauges 123 are configured to measure the pressures of the respective parts within the reaction tube 2 and within the exhaust pipe, and notify the measured values to the control unit 100.

The heater controller 124 is configured to individually control the heaters 7. In response to the instructions received from the control unit 100, the heater controller 124 allows an electric current to be supplied to the heaters 7, thereby causing the heaters 7 to generate heat. Moreover, the heater controller 124 measures the respective power consumptions of the heaters 7 and notifies the measured power consumptions to the control unit 100.

The MFCs 125 are installed in the respective pipes of the source gas supply pipe 8, the first oxidizing gas supply pipe 9, the nitrogen gas supply pipe 10, the second oxidizing gas supply pipe 11 and the cleaning gas supply pipe 12. The MFCs 125 control the flow rates of the gases flowing through the respective pipes at the rates instructed by the control unit 100. Further, the MFCs 125 measure the actual flow rates of the gases and notify the measured flow rates to the control unit 100.

The valve controllers 126 are installed in the respective pipes and control the opening degrees of the valves installed in the respective pipes at the values instructed by the control unit 100. The vacuum pump 127 is connected to the exhaust pipe and discharges the gas within the reaction tube 2.

The boat elevator 128 moves the lid 5 upward to thereby load the wafer boat 6 (semiconductor wafers W) into the reaction tube 2. The boat elevator 128 moves the lid 5 downward to thereby unload the wafer boat 6 (semiconductor wafers W) from the interior of the reaction tube 2.

The control unit 100 includes a recipe storage unit 111, a ROM (Read Only Memory) 112, a RAM (Random Access Memory) 113, an I/O port (Input/Output port) 114, a CPU (Central Processing Unit) 115, and a bus 116 configured to interconnect them.

A setup recipe and a plurality of process recipes are stored in the recipe storage unit 111. At the time of manufacture of the processing apparatus 1, only the setup recipe is stored in the recipe storage unit 111. The setup recipe is executed to generate thermal models and the like in conformity with individual processing apparatuses. A process recipe is prepared for each of the heat treatments (processes) actually performed by a user. Each of the process recipes defines the temperature changes of the respective parts, the pressure changes within the reaction tube 2, and the supply start/stop timings and the supply amounts of various types of gases, during the time period from the time when the semiconductor wafers W are loaded into the reaction tube 2 to the time when the processed semiconductor wafers W are unloaded from the reaction tube 2.

The ROM 112 is configured by an EEPROM (Electrically Erasable Programmable Read Only Memory), a flash memory, a hard disk or the like. The ROM 112 is a recording medium that stores an operation program of the CPU 115. The RAM 113 serves as a work area of the CPU 115.

The I/O port 114 is connected to the manipulation panel 121, the temperature sensors 122, the pressure gauges 123, the heater controller 124, the MFCs 125, the valve controllers 126, the vacuum pump 127, the boat elevator 128 and so forth, and controls the input and output of data and signals.

The CPU 115 constitutes a core of the control unit 100 and executes the operation program stored in the ROM 112. Further, in response to the instructions received via the manipulation panel 121, the CPU 115 controls the operation of the processing apparatus 1 pursuant to the recipes (process recipes) stored in the recipe storage unit 111. That is, the CPU 115 causes the temperature sensors 122, the pressure gauges 123 and the MFCs 125 to measure the temperatures, pressures and flow rates of the respective parts within the reaction tube 2 and within the exhaust pipe. Based on the measured data, the CPU 115 outputs control signals to the heater controller 124, the MFCs 125, the valve controllers 126, the vacuum pump 127 and so forth, and thereby controls the respective parts in accordance with the process recipes. The bus 116 delivers information between the respective parts.

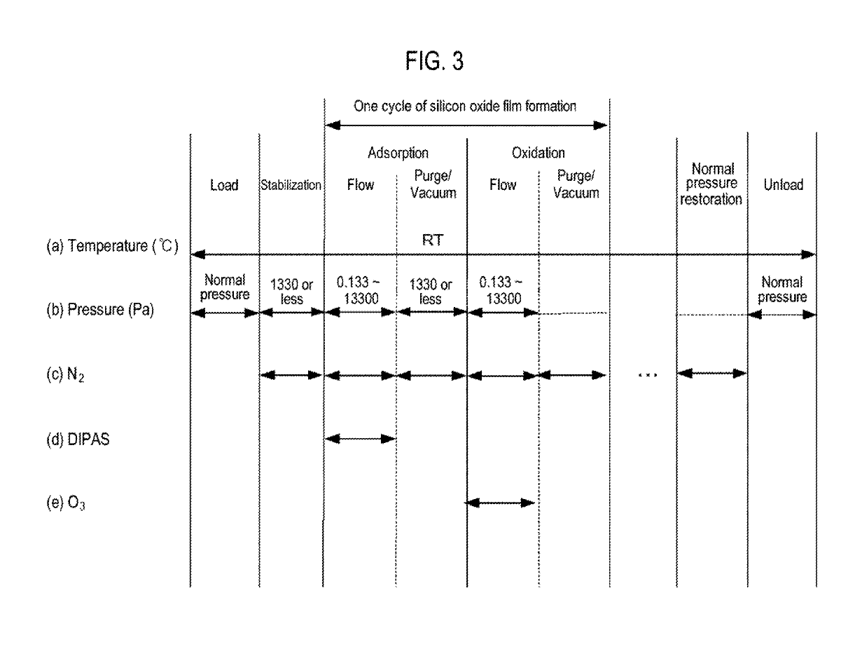

Next, a silicon oxide film forming method using the processing apparatus 1 configured as above will be described with reference to the recipe (time sequence) shown in FIG. 3. In the silicon oxide film forming method of the present embodiment, a silicon oxide film is formed on a semiconductor wafer W by an ALD method.

As shown in FIG. 3, the silicon oxide film forming method of the present embodiment includes an adsorption step to have silicon (Si) adsorbed to the surface of the semiconductor wafer W and an oxidation step to oxidize the adsorbed Si adsorption. These steps form one cycle of the ALD method. In the present embodiment, as shown in FIG. 3, diisopropylaminosilane (DIPAS), ozone (O₃) and nitrogen (N₂) are used as a Si source gas, an oxidizing gas and a diluting gas, respectively. The cycle shown in FIG. 3 is performed (or repeated) a plurality of times, e.g., one hundred times, whereby a silicon oxide film having a desired thickness is formed on the semiconductor wafer W.

In the following description, the operations of the respective parts forming the processing apparatus 1 are controlled by the control unit 100 (CPU 115). Further, the control unit 100 (CPU 115) controls the heater controller 124 (heaters 7), the MFCs 125 (source gas supply pipe 8, etc.), the valve controllers 126 and the vacuum pump 127 in the aforementioned manner, so that the temperature, pressure and flow rates of gases in the reaction tube 2 in the respective processes are set into the conditions conforming to the recipe shown in FIG. 3.

First, by the heaters 7, the interior of the reaction tube 2 is maintained at a predetermined loading temperature, e.g., at room temperature (RT) as shown in FIG. 3. The internal temperature of the reaction tube 2 may be in a range of RT to 700 degrees C., in a range of RT to 400 degrees C., and in a range of RT to 300 degrees C.

Then, the wafer boat 6 accommodating the semiconductor wafers W is mounted on the lid 5. The lid 5 is moved up by the boat elevator 128, thereby loading the semiconductor wafers W (wafer boat 6) into the reaction tube 2 (load process).

Subsequently, the internal temperature of the reaction tube 2 is set at a predetermined temperature, e.g., at RT as shown in (a) of FIG. 3, using the heaters 7. Further, a predetermined amount of nitrogen is supplied from the nitrogen gas supply pipe 10 into the reaction tube 2 while discharging the gas within the reaction tube 2. Thus, the internal pressure of the reaction tube 2 is set at a predetermined pressure, e.g., 1330 Pa (10 Torr) or less as shown in (b) of FIG. 3 (stabilization process).

Then, an adsorption step to have Si adsorbed onto the surface of the semiconductor wafer W is performed. The adsorption step is a step at which a source gas is supplied to the semiconductor wafer W to have Si adsorbed onto the surface of the semiconductor wafer W. At the adsorption step, a predetermined amount of DIPAS as a Si source is supplied from the source gas supply pipe 8 as shown in (d) of FIG. 3 and a predetermined amount of nitrogen is supplied into the reaction tube 2 as shown in (c) of FIG. 3 (flow process).

In this regard, the internal temperature of the reaction tube 2 may be set to fall within a range of room temperature (RT) to 700 degrees C. This is because, if the internal temperature of the reaction tube 2 becomes lower than room temperature, it may be impossible to form a silicon oxide film. In some embodiments, the internal temperature of the reaction tube 2 may be set to fall within a range of RT to 400 degrees C. In other embodiments, the internal temperature of the reaction tube 2 may be set to fall within a range of RT to 300 degrees C.

The internal pressure of the reaction tube 2 may be from 0.133 Pa (0.001 Torr) to 13.3 kPa (100 Torr) in some embodiments. If the internal pressure of the reaction tube 2 is set in this range, the reaction of Si with the surface of the semiconductor wafer W can be accelerated. In some other embodiments, the internal pressure of the reaction tube 2 may be from 40 Pa (0.3 Torr) to 4,000 Pa (30 Torr). If the internal pressure of the reaction tube 2 is set in this range, it becomes easy to control the internal pressure of the reaction tube 2.

DIPAS supplied into the reaction tube 2 is activated within the reaction tube 2. For that reason, upon supplying DIPAS into the reaction tube 2, the activated Si reacts with the surface of the semiconductor wafer W and is adsorbed to the surface of the semiconductor wafer W.

If a predetermined amount of Si is adsorbed to the surface of the semiconductor wafer W, the supply of DIPAS from the source gas supply pipe 8 and the supply of nitrogen from the nitrogen gas supply pipe 10 are stopped. Then, the gas existing within the reaction tube 2 is discharged to the outside of the reaction tube 2, while a predetermined amount of nitrogen is supplied from the nitrogen gas supply pipe 10 into the reaction tube 2, for example, as shown in (c) of FIG. 3, (purge/vacuum process).

Subsequently, the internal temperature of the reaction tube 2 is set at a predetermined temperature, e.g., at RT as shown in (a) of FIG. 3, using the heaters 7. Also, as shown in (c) of FIG. 3, a predetermined amount of nitrogen is supplied from the nitrogen gas supply pipe 10 into the reaction tube 2, while discharging the gas existing within the reaction tube 2. Thus, the internal pressure of the reaction tube 2 is set at a predetermined pressure, e.g., 1330 Pa (10 Torr) or less as shown in (b) of FIG. 3.

Then, the oxidation step for oxidizing the surface of the semiconductor wafer W is performed. At the oxidation step, an oxidizing gas is supplied onto the Si-adsorbed semiconductor wafer W to oxidize the adsorbed Si. In the present embodiment, the adsorbed Si is oxidized by supplying ozone (O₃) onto the semiconductor wafer W.

At the oxidation step, a predetermined amount of ozone is supplied from the first oxidizing gas supply pipe 9 into the reaction tube 2 as shown in (e) of FIG. 3. Further, as shown in (c) of FIG. 3, a predetermined amount of nitrogen as a diluting gas is supplied from the nitrogen gas supply pipe 10 into the reaction tube 2 (flow process).

The internal pressure of the reaction tube 2 may be from 0.133 Pa (0.001 Torr) to 13.3 kPa (100 Torr) in some embodiments. If the internal pressure of the reaction tube 2 is set in this range, the oxidization of Si existing on the surface of the semiconductor wafer W can be accelerated. In some other embodiments, the internal pressure of the reaction tube 2 may be from 40 Pa (0.3 Torr) to 4,000 Pa (30 Torr). If the internal pressure of the reaction tube 2 is set in this range, it becomes easy to control the internal pressure of the reaction tube 2.

If ozone is supplied into the reaction tube 2, the Si adsorbed to the surface of the semiconductor wafer W is oxidized to form a silicon oxide film on the semiconductor wafer W. If a silicon oxide film having a desired thickness is formed on the semiconductor wafer W, the supply of ozone from the first oxidizing gas supply pipe 9 is stopped. Further, the supply of nitrogen from the nitrogen gas supply pipe 10 is stopped. Then, the gas existing within the reaction tube 2 is discharged to the outside of the reaction tube 2, while a predetermined amount of nitrogen is supplied from the nitrogen gas supply pipe 10 into the reaction tube 2, as shown in FIG. 3 (purge/vacuum process).

By performing the purge/vacuum process at the oxidation step, one cycle of the ALD method including the adsorption step and the oxidation step is finished. Subsequently, another cycle of the ALD method may start from the adsorption step, and such a cycle may be repeated a predetermined number of times. In this manner, a silicon oxide film having a desired thickness is formed on the semiconductor wafer W.

When the silicon oxide film having a desired thickness is formed on the semiconductor wafer W, the interior of the reaction tube 2 is maintained at a predetermined loading temperature, e.g., at RT as shown in (a) of FIG. 3, using the heaters 7. At the same time, the interior of the furnace is cycle-purged with N₂ and is returned to the normal pressure (normal pressure restoration process). Finally, the lid 5 is moved down by the boat elevator 128, thereby unloading the semiconductor wafers W (unload process).

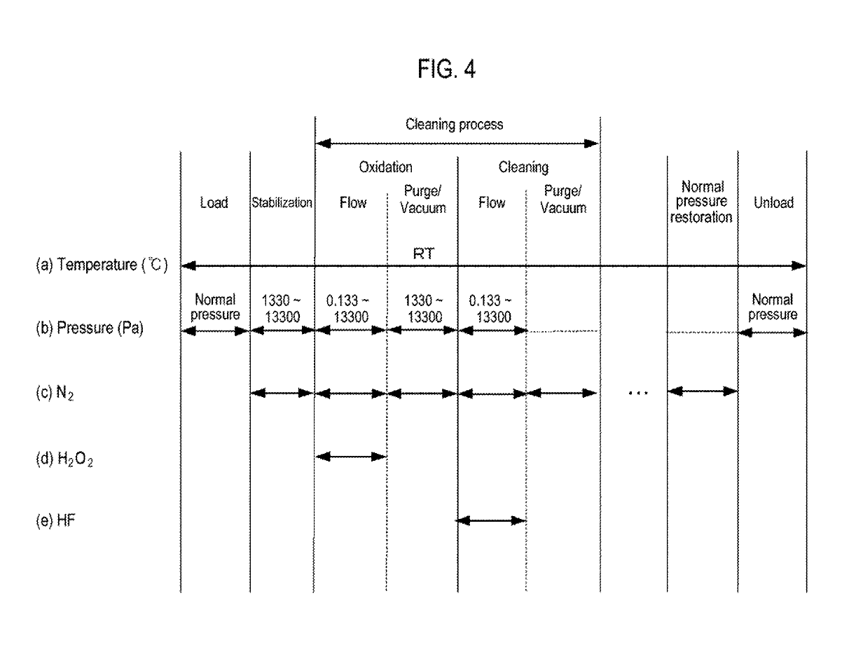

If the silicon oxide film forming process described above is performed a plurality of times, the reaction product thus formed is deposited on (or adheres to) not only the surfaces of the semiconductor wafers W but also the inner surface of the reaction tube 2 and various kinds of jigs. For that reason, after performing the silicon oxide film forming process a predetermined number of times, a cleaning process to remove a deposit adhering to the inside of the processing apparatus 1 is performed. FIG. 4 is a view for explaining a cleaning method of the processing apparatus 1. As shown in FIG. 4, the cleaning process includes an oxidation step to oxidize the deposit adhering to the inside of the processing apparatus 1 (reaction tube 2) and to remove carbons or the like from the deposit, and a cleaning step to remove (clean) the deposit from which carbon or the like is removed.

As shown in FIG. 4, in the present embodiment, hydrogen peroxide (H₂O₂) is used as the oxidizing gas. Hydrogen fluoride (HF) is used as the cleaning gas. Nitrogen (N₂) is used as the diluting gas. The deposit adhering to the inside of the processing apparatus 1 is removed by performing (repeating) the cycle, indicated in the recipe of FIG. 4, a predetermined number of times. Hereinafter, the cleaning process of the processing apparatus 1 will be described.

First, by virtue of the heaters 7, the interior of the reaction tube 2 is maintained at a predetermined loading temperature, e.g., at RT as shown in (a) of FIG. 4. Then, the wafer boat 6, not accommodating the semiconductor wafers W, is mounted on the lid 5. Then, the lid 5 is moved up by the boat elevator 128, thereby loading the wafer boat 6 into the reaction tube 2 (load process).

Subsequently, by virtue of the heaters 7, the internal temperature of the reaction tube 2 is maintained at a predetermined temperature, e.g., at RT as shown in (a) of FIG. 4. A predetermined amount of nitrogen is supplied from the nitrogen gas supply pipe 10 into the reaction tube 2 while discharging the gas existing within the reaction tube 2. The internal pressure of the reaction tube 2 is set at a predetermined pressure, e.g., at a pressure of 1,330 Pa (10 Torr) to 13,300 Pa (100 Torr) (stabilization process).

Then, the oxidation step to oxidize the deposit adhering to the inside of the reaction tube 2 and to remove carbon or the like from the deposit, is performed. The oxidation step is to oxidize the deposit adhering to the inside of the reaction tube 2 by supplying an oxidizing gas into the reaction tube 2, and thereby remove carbon or the like (carbon, nitrogen or the like) from the deposit. At the oxidation step, a predetermined amount of hydrogen peroxide (H₂O₂) is supplied from the second oxidizing gas supply pipe 11 as shown in (d) of FIG. 4 and a predetermined amount of nitrogen is supplied into the reaction tube 2 as shown in (c) of FIG. 4 (flow process).

The concentration of carbon in the silicon oxide film is higher in the lower portion of the reaction tube, in which a film tends to remain despite the supply of the cleaning gas such as hydrogen fluoride or the like at room temperature, than in a product processing region. For that reason, if the silicon oxide film containing carbon is accumulated, the carbon contained in the film is diffused to and segregated on an oxide film/quartz interface over time. Thus, the silicon oxide film becomes a film similar to a SiOC film. As a result, the film cannot be removed despite the supply of the cleaning gas such as hydrogen fluoride (HF) or the like. In view of this, a deposit similar to a SiOC film is oxidized to remove carbon or the like from the deposit, thereby changing the deposit into a silicon oxide film. Thereafter, the deposit is removed with the cleaning gas such as hydrogen fluoride (HF) or the like.

In this regard, the internal temperature of the reaction tube 2 may be from RT to 400 degrees C. If the internal temperature of the reaction tube 2 becomes lower than room temperature, it may be impossible to remove carbon or the like from the deposit or it may be impossible to remove the deposit with the cleaning gas. In some embodiments the internal temperature of the reaction tube 2 may be set to fall within a range of RT to 300 degrees C. In other embodiments, the internal temperature of the reaction tube 2 may be set to fall within a range of RT to 200 degrees C.

The internal pressure of the reaction tube 2 may be from 0.133 Pa (0.001 Torr) to 13.3 kPa (100 Torr) in some embodiments. If the internal pressure of the reaction tube 2 is set in this range, the reaction of the deposit with the oxidizing gas can be accelerated. In some embodiments, the internal pressure of the reaction tube 2 may be from 1,330 Pa (10 Torr) to 13.3 kPa (100 Torr). If the internal pressure of the reaction tube 2 is set in this range, it becomes easy to control the internal pressure of the reaction tube 2.

The hydrogen peroxide supplied into the reaction tube 2 is activated within the reaction tube 2. Thus, if hydrogen peroxide is supplied into the reaction tube 2, the surface of the deposit reacts with the activated hydrogen peroxide, whereby the deposit is oxidized and carbon is removed from the deposit.

If carbon is removed from the deposit, the supply of hydrogen peroxide from the second oxidizing gas supply pipe 11 and the supply of nitrogen from the nitrogen gas supply pipe 10 are stopped. Then, the gas existing within the reaction tube 2 is discharged. For example, as shown in (c) of FIG. 4, a predetermined amount of nitrogen is supplied from the nitrogen gas supply pipe 10 into the reaction tube 2, thereby discharging the gas existing within the reaction tube 2 outside of the reaction tube 2 (purge/vacuum process).

Subsequently, by virtue of the heaters 7, the internal temperature of the reaction tube 2 is maintained at a predetermined temperature, e.g., at RT as shown in (a) of FIG. 4. As shown in (c) of FIG. 4, a predetermined amount of nitrogen is supplied from the nitrogen gas supply pipe 10 into the reaction tube 2 while discharging the gas existing within the reaction tube 2. The internal pressure of the reaction tube 2 is set at a predetermined pressure, e.g., at a pressure of 1,330 Pa (10 Torr) to 13,300 Pa (100 Torr).

Then, the cleaning step to remove (clean) the deposit, from which carbon or the like is removed, is performed. The cleaning step is a step at which the deposit is removed by supplying the cleaning gas to the deposit (i.e., the silicon oxide film) from which carbon or the like is removed. In the present embodiment, the deposit is removed by supplying hydrogen fluoride (HF) into the reaction tube 2.

At the cleaning step, as shown in (e) of FIG. 4, a predetermined amount of hydrogen fluoride (HF) is supplied from the cleaning gas supply pipe 12 into the reaction tube 2. Furthermore, as shown in (c) of FIG. 4, a predetermined amount of nitrogen as a diluting gas is supplied from the nitrogen gas supply pipe 10 into the reaction tube 2 (flow process).

The internal pressure of the reaction tube 2 may be from 0.133 Pa (0.001 Torr) to 13.3 kPa (100 Torr) in some embodiments. If the internal pressure of the reaction tube 2 is set in this range, the reaction of hydrogen fluoride can be accelerated. In some embodiments, the internal pressure of the reaction tube 2 may be from 1,330 Pa (10 Torr) to 13,300 Pa (100 Torr). If the internal pressure of the reaction tube 2 is set in this range, it becomes easy to control the internal pressure of the reaction tube 2.

If hydrogen fluoride is supplied into the reaction tube 2, the deposit existing within the reaction tube 2 is removed. Upon removing the deposit existing within the reaction tube 2, the hydrogen fluoride supply from the cleaning gas supply pipe 12 is stopped. Further, the supply of nitrogen from the nitrogen gas supply pipe 10 is stopped. Then, the gas existing within the reaction tube 2 is discharged. As shown in (c) of FIG. 4, a predetermined amount of nitrogen is supplied from the nitrogen gas supply pipe 10 into the reaction tube 2, thereby discharging the gas existing within the reaction tube 2 outside of the reaction tube 2 (purge/vacuum process).

Thus, the cleaning process including the oxidation step and the cleaning step is completed. If necessary, the cleaning process including the oxidation step and the cleaning step may be repeated a plurality of times. Thus, the deposit adhering to the inside of the reaction tube 2 is removed.

If the deposit is removed, the interior of the reaction tube 2 is maintained at a predetermined loading temperature, e.g., at RT as shown in (a) of FIG. 4, using the heaters 7. At the same time, the interior of the furnace is cycle-purged with N₂ and is returned to the normal pressure (normal pressure restoration process). Finally, the lid 5 is moved down by the boat elevator 128, thereby unloading the semiconductor wafers W (unload process).

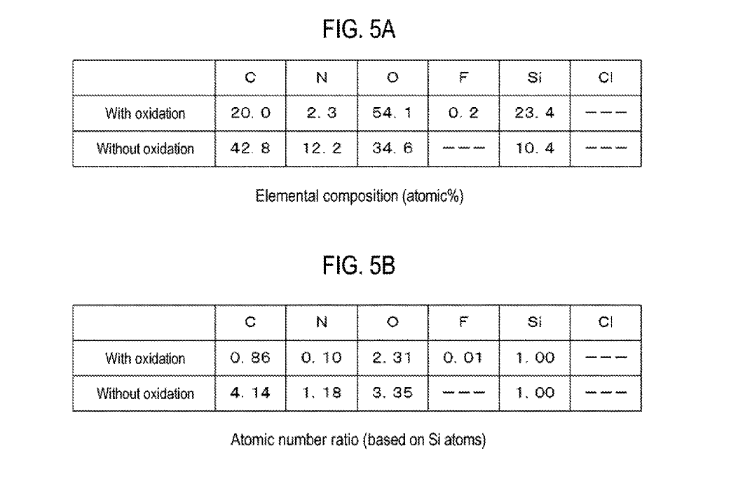

Then, in order to confirm the effects of the present disclosure, the elemental composition and the atomic number ratio of the deposit, in the case of performing the oxidation step of the cleaning process and in the case of not performing the oxidation step, were measured by X-ray photoelectron spectroscopy (XPS). The results are shown in FIGS. 5A and 5B. FIG. 5A shows the elemental composition of the deposit (atomic %) and FIG. 5B shows the atomic number ratio (based on Si atoms).

As shown in FIGS. 5A and 5B, it can be confirmed that, by performing the oxidation step of the cleaning process, carbon and nitrogen are significantly reduced and the deposit becomes similar to the silicon oxide film.

Further, the inside of the reaction tube 2 subjected to the cleaning process was checked in the case of performing the oxidation step of the cleaning process and in the case of not performing the oxidation step. As a result of the check, it was confirmed that there is a residual film on the lower inner wall of the reaction tube 2 in the case of not performing the oxidation step while there is no residual film on the lower inner wall of the reaction tube 2 as well as the inner wall of the reaction tube 2 in the case of performing the oxidation step.

As described above, according to the present embodiment, the oxidation step is performed prior to the cleaning step of the cleaning process. It is therefore possible to remove the deposit adhering to the inside of the reaction tube 2 and to prevent a so-called residual film. Thus, it is possible to suppress generation of particles and to improve productivity even at a low temperature such as RT or the like.

The present disclosure is not limited to the aforementioned embodiment but may be modified and applied in many different forms. Hereinafter, other embodiments applicable to the present disclosure will be described.

In the aforementioned embodiment, the present disclosure has been described by taking as an embodiment where DIPAS is used as the Si source. However, the Si source only needs to be an organic source gas capable of forming a silicon oxide film. For example, SiH₄, SiH₃Cl, SiH₂Cl₂, SiHCl₃, SiH₃(NHC(CH₃)₃), SiH₃(N(CH₃)₂), SiH₂(NHC(CH₃)₃)₂ and SiH(N(CH₃)₂)₃, may be used as the Si source.

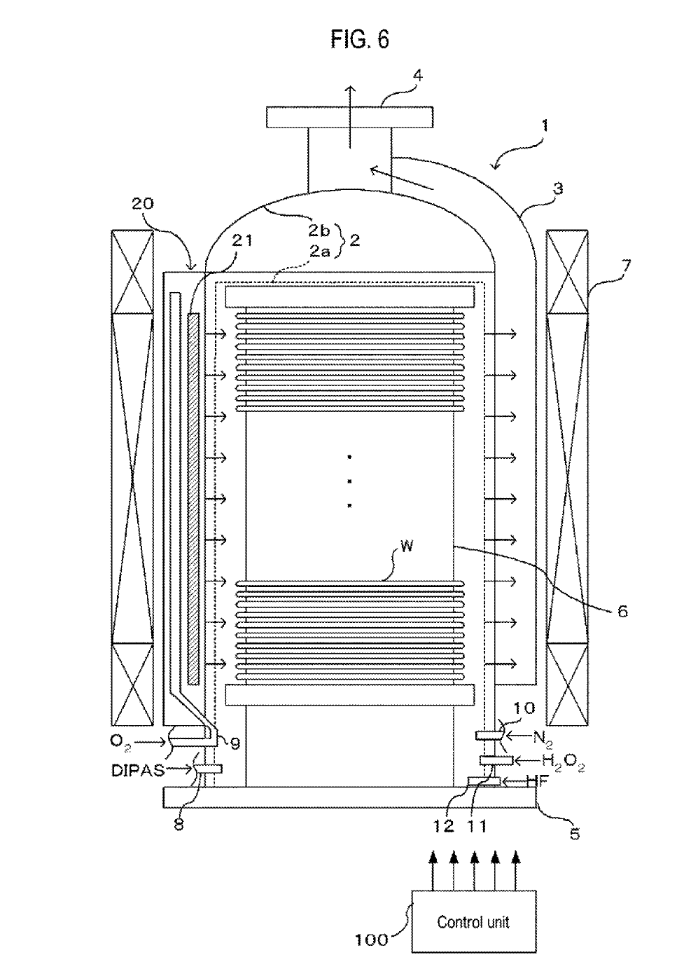

In the aforementioned embodiment, the present disclosure has been described by taking as an embodiment where ozone is used as the oxidizing gas. However, the oxidizing gas only needs to be a gas capable of oxidizing the adsorbed Si to form a silicon oxide film. For example, oxygen radicals generated by treating oxygen (O₂) with plasma, catalysts, ultraviolet rays, heat, magnetic forces or the like, may be used as the oxidizing gas. In the case where the oxidizing gas is activated by, e.g., plasma, it may be possible to use a processing apparatus 1 shown in FIG. 6.

In the processing apparatus 1 shown in FIG. 6, a plasma generating unit 20 is installed at the opposite side of the reaction tube 2 from the side where the exhaust part 3 is disposed. The plasma generating unit 20 is provided with a pair of electrodes 21. The oxidizing gas supply pipe 9 is inserted between the electrodes 21. The electrodes 21 are connected to a high-frequency power supply, a matching unit and so forth, all of which are not shown. High-frequency electric power from the high-frequency power supply is applied between the electrodes 21 through the matching unit, thereby plasma-exciting (activating) the oxidizing gas (O₂) between the electrodes 21, and consequently generating oxygen radicals (O₂*). The oxygen radicals (O₂*) thus generated is supplied from the plasma generating unit 20 into the reaction tube 2.

In the present embodiment, the present disclosure has been described by taking an example where hydrogen peroxide is used as the oxidizing gas. However, it is only necessary that the oxidizing gas is capable of removing carbon or the like contained in the deposit. Various kinds of oxidizing agents may be used. However, hydrogen peroxide or the like which has oxidizing power even at a low temperature such as RT or the like may be used.

In the aforementioned embodiment, the present disclosure has been described by taking an example where the silicon oxide film is formed on the semiconductor wafer W by performing one hundred cycles of the oxide film formation process. As an alternative example, the number of cycles may be reduced to, e.g., fifty cycles. Further, the number of cycles may be increased to, e.g., two hundred cycles. Even in these cases, a silicon oxide film having a desired thickness can be formed by adjusting, e.g., the supply amounts of the Si source and the oxygen based on the number of cycles.

In the aforementioned embodiment, the present disclosure has been described by taking an example where the nitrogen as the diluting gas is supplied during the supply of the source gas and the oxidizing gas. Alternatively, the nitrogen may not be supplied during the supply of the source gas and the oxidizing gas. However, since it becomes easy to set the processing time and the like by including the nitrogen as the diluting gas, supplying the diluting gas may be beneficial. The diluting gas may be an inert gas other than the nitrogen, e.g., helium (He), neon (Ne), argon (Ar), krypton (Kr) or xenon (Xe).

In the aforementioned embodiment, the present disclosure has been described by taking an example where the silicon oxide film is formed on the semiconductor wafer W using the ALD method. However, the present disclosure is not limited to the use of the ALD method. The silicon oxide film may be formed on the semiconductor wafer W by a CVD (Chemical Vapor Deposition) method.

In the aforementioned embodiment, the present disclosure has been described by taking an example where the batch-type processing apparatus having a double tube structure is used as the processing apparatus 1. As an alternative example, the present disclosure may be applied to a batch-type processing apparatus having a single tube structure. Further, the present disclosure may be applied to a batch-type horizontal processing apparatus or a single-substrate-type processing apparatus. In addition, the workpiece is not limited to the semiconductor wafer W but may be, e.g., a glass substrate for an LCD (Liquid Crystal Display).

The control unit 100 employed in the embodiments of the present disclosure can be realized by using a typical computer system instead of a dedicated computer system. For example, the control unit 100 for performing the aforementioned processes can be configured by installing programs for executing the processes into a general-purpose computer through a recording medium (a flexible disc, a CD-ROM (Compact Disc-Read Only Memory) or the like) which stores programs for performing the aforementioned processes.

The programs can be provided by an arbitrary means. The programs may be provided not only by the recording medium mentioned above but also through a communication line, a communication network, a communication system or the like. In the latter case, the programs may be posted in network bulletin boards (BBS: Bulletin Board System) and provided through a network together. The program thus provided is started up and executed in the same manner as other application programs under the control of an operating system, thereby performing the processes described above.

The present disclosure is useful in a cleaning method of a silicon oxide film forming apparatus, a silicon oxide film forming method and a silicon oxide film forming apparatus.

According to the present disclosure in some embodiments, it is possible to suppress generation of particles even at a low temperature such as a room temperature or the like and to improve productivity.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A cleaning method of a silicon oxide film forming apparatus for removing a deposit adhering to the inside of the silicon oxide film forming apparatus after a silicon oxide film is formed on a workpiece by supplying a process gas into a reaction chamber of the silicon oxide film forming apparatus, comprising:
oxidizing the deposit adhering to the inside of the silicon oxide film forming apparatus by supplying an oxidizing gas into the reaction chamber; and
cleaning the inside of the silicon oxide film forming apparatus by supplying a cleaning gas into the reaction chamber and removing the oxidized deposit.

2. The cleaning method of claim 1, wherein the oxidizing the deposit removes carbon from the deposit adhering to the inside of the silicon oxide film forming apparatus.

3. The cleaning method of claim 1, wherein the interior of the reaction chamber is maintained at a room temperature during the oxidizing the deposit and the cleaning the inside of the silicon oxide film forming apparatus.

4. The cleaning method of claim 1, wherein the oxidizing gas is a hydrogen peroxide gas.

5. A silicon oxide film forming method, comprising:
forming a silicon oxide film on a workpiece; and
cleaning the inside of a silicon oxide film forming apparatus according to the cleaning method of claim 1.

6. A silicon oxide film forming apparatus for forming a silicon oxide film on a workpiece by supplying a process gas into a reaction chamber which accommodates the workpiece therein, comprising:
an oxidizing gas supply unit configured to supply an oxidizing gas into the reaction chamber;
a cleaning gas supply unit configured to supply a cleaning gas into the reaction chamber; and
a control unit configured to control the oxidizing gas supply unit and the cleaning gas supply unit,
wherein the control unit is configured to control the oxidizing gas supply unit so as to supply the oxidizing gas into the reaction chamber and remove carbon from a deposit adhering to the inside of the apparatus by oxidizing the deposit, and wherein the control unit is configured to control the cleaning gas supply unit so as to supply the cleaning gas into the reaction chamber and clean the inside of the silicon oxide film forming apparatus by removing the deposit from which carbon is removed.
